(19) United States
(12) Patent Application Publication
(10) Pub. No.: US 2025/0112139 A1
(43) Pub. Date: Apr. 3, 2025

(54) VIAS THROUGH A DIE THAT ARE ELECTRICALLY ISOLATED FROM ACTIVE CIRCUITRY IN THE DIE

(71) Applicant: Intel Corporation, Santa Clara, CA (US)

(72) Inventors: Abdallah BACHA, Munich (DE); Thomas WAGNER, Regelsbach (DE); Cindy MUIR, Tempe (OR); Mohan Prashanth JAVARE GOWDA, Ottobrunn (DE); Stephan STOECKL, Schwandorf (DE); Wolfgang MOLZER, Ottobrunn (DE)

(21) Appl. No.: 18/374,954

(22) Filed: Sep. 29, 2023

(51) Int. Cl. H01L 23/498; H01L 21/48; H01L 23/31; H01L 23/48; H01L 23/538; H01L 25/065

(52) U.S. Cl. CPC H01L 23/49827; H01L 23/3128; H01L 23/481; H01L 23/49816; H01L 23/5389; H01L 25/0652; H01L 21/486

(57) ABSTRACT

Embodiments herein relate to systems, apparatuses, or processes for forming a die that has active circuitry within the die and also one or more vias that extend through the die that are electrically isolated from the active circuitry. In embodiments, the active circuitry may be within a region within a die, for example in the center of the die, and the vias may be in an extended area around the active circuitry of the die. In embodiments, an existing die may be provided, and an extended area may be formed on the existing die into which the vias may be placed. Other embodiments may be described and/or claimed.

Embodiments of the present disclosure generally relate to the package assemblies, and in particular package assemblies that include dies with active circuitry.

### BACKGROUND

Continued reduction in end product size of electronic devices such as smart phones, ultrabooks, and desktops, as well as systems in datacenters, is a driving force for the development of reduced-size package components within systems with increased performance.

### BRIEF DESCRIPTION OF THE DRAWINGS

FIG. 1 illustrates a cross-section side view and a perspective view of a legacy package that includes a die between a substrate and an interposer, where the die is not directly electrically coupled with the substrate.

FIG. 2 illustrates perspective views of a die with an active circuitry area and a die with an extended area around the active circuitry area through which vias may be formed, in accordance with various embodiments.

FIG. 3 illustrates top-down views of various configurations of a die with an active circuitry area and an extended area through which vias are formed, in accordance with various embodiments.

FIG. 4 illustrates a cross-section side view of a structure and example electrical routing of a package that includes a die with active circuitry area and an extended area through which vias are formed, in accordance with various embodiments.

FIGS. 5A-5B illustrate cross-section side views of package that includes multiple stacked dies each with an active circuitry area and an extended area through which vias are formed, in accordance with various embodiments.

FIGS. 6A-6B illustrate cross-section side views of package that includes two dies that are direct bonded with each other, with each die having an active circuitry area and an extended area through which vias are formed, in accordance with various embodiments.

FIGS. 7A-7B illustrate cross-section side views of the package that includes multiple stacked dies each with an active circuitry area and an extended area through which vias are formed, with the top and bottom of the stacked dies including a redistribution layer (RDL) to route power or signals from the vias, in accordance with various embodiments.

FIG. 8 illustrates a cross-section side view of a die with an active circuitry area and extended area through which vias are formed, where the extended area includes a power via and a signal via, in accordance with various embodiments.

FIG. 9 illustrates a cross-section side view of a die with an active circuitry area and extended area through which vias are formed, where the extended area includes a via that is shielded, in accordance with various embodiments.

FIGS. 10A-10D illustrate cross-section side views and a top-down view of a die with an active circuitry area and extended area through which vias are formed, where the extended area includes vias that are coupled with each other that form a capacitor or that form a diode, in accordance with various embodiments.

FIG. 11 illustrates an example of a process for creating vias through a die that are electrically isolated from active circuitry in a die, in accordance with various embodiments.

FIG. 12 schematically illustrates a computing device, in accordance with embodiments.

### DETAILED DESCRIPTION

Embodiments of the present disclosure may generally relate to systems, apparatus, techniques, and/or processes directed to forming a die that has active circuitry within the die and also one or more vias that extend through the die that are electrically isolated from the active circuitry. In embodiments, the active circuitry may be within a region within a die, for example in the center of the die, and the vias may be in an area around the active circuitry. In embodiments, an existing die may be provided, and an extended area may be formed on the existing die through which the vias may be placed.

Increasingly, high performance computing power chips are designed in a chiplet package architecture that includes an interposer. This architecture increases the X/Y dimensions of the package size, and as a result double-sided attached dies may be used that are coupled with an interposer to avoid further increase of the package size. This also serves to shorten a distance of high-speed signals between chips because they are able to now be connected through the interposer. However, when the die is between a substrate and an interposer, signal and/or power from a location in the substrate below the die to a location in the interposer above the die in legacy implementations is routed around the die. This legacy indirect routing may be through vias that directly electrically couple the substrate and the interposer causing the signal/power to be routed around the die.

In embodiments described herein, vias may be formed within the die to facilitate signal and/or power routing through these vias, therefore reducing the overall length of the route. In embodiments, this reduction of overall length may improve the signal and/or power connection between the substrate and the interposer. In embodiments, this may result in faster performance of the package, increased quality of the signal, and reducing the amount of electromagnetic interference generated during operation of the package in comparison with legacy implementations.

In particular, embodiments that add an extended area around an existing die have the advantage of customizing vias to route power and/or signal through the extended area without having to change the original design of the active circuitry within the existing die. In this way, a single die with a particular active circuitry design may be used in multiple different configurations of a package. In addition, the vias may also include various electrical features, such as capacitors or diodes, that may not functionally affect the active circuitry within the die. In embodiments, the die may be a memory, however in other embodiments the die may be a functional die or an Integrated Passive Device (IPD), which may include capacitors, inductors, and/or resistors.

In embodiments, these techniques may result in a denser and shorter signal and power supply, as the normal placed copper pillar bumps may achieve due to the larger keep out zone from the die edge to the copper pillar bumps. For example, for a die that is located between a substrate and an interposer, a gap between the die edge and the first possible copper pillars between the interposer and the substrate is always larger than the distance of through silicon vias next to the active area on the die. Due to die placement tolerances, an electrical route around the die will increase routing distance.

In addition, because the vias in the extended area are within the die, the vias have a much smaller keep out zone, for example on the order of 10 μm versus 100 μm or larger in legacy implementations. In legacy implementations, larger keep out zones may also block routing and transistor placements in this area, leading to larger die schematics, which may be referred to as macros, and more silicon area requirement.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

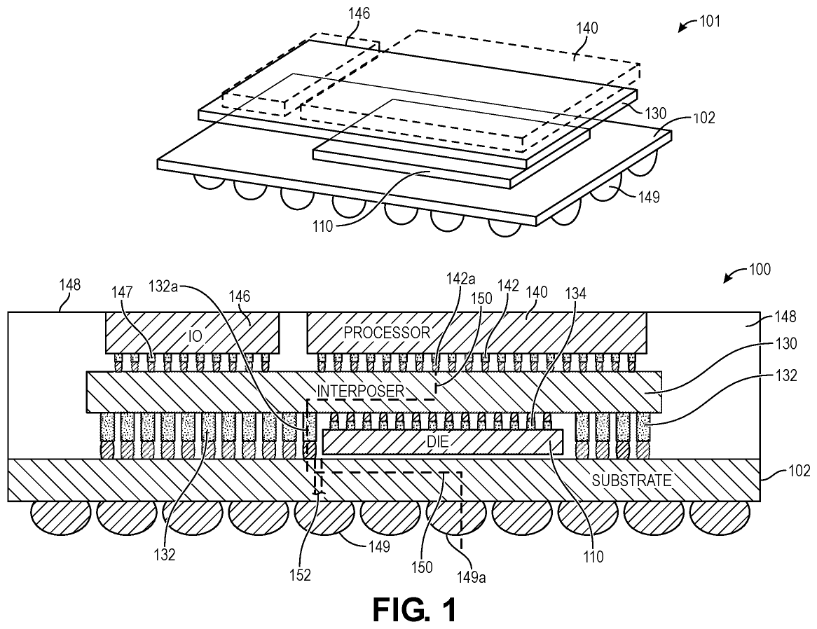

FIG. 1 illustrates a cross-section side view and a perspective view of a legacy package that includes a die between a substrate and an interposer, where the die is not directly electrically coupled with the substrate. Package 100 includes a substrate 102, a die 110 that is on the substrate 102, and an interposer 130 that is on the die 110 and on the substrate 102. A processor die 140 and an input/output (I/O) die 146 may be on the interposer 130. In implementations, the die 110 may be a functional die or may be a memory die. In implementations, the die 110 may be a high bandwidth memory die (HBM). In implementations, a mold compound 148 may surround or partially surround the substrate 102, die 110, interposer 130, processor 140, and/or I/O die 146.

Solder balls 149 may be coupled to a bottom side of the substrate 102. The solder balls 149 may attach to a printed circuit board (PCB) and may bring power or signal through the solder balls 149 into the package 100. The substrate 102 may be directly electrically coupled with the interposer 130 using bumps/pillars 132. The die 110 may be directly electrically coupled with the interposer 130 using bumps/pillars 134. The processor 140 may be directly electrically coupled with the interposer 130 using bumps/pillars 142, and the I/O die 146 may be directly electrically coupled with the interposer 130 using bumps/pillars 147.

In one example of routing of a signal from solder ball 149a to bump/pillar 142a coupled with the processor 140, where the die 110 is between the substrate 102 and the processor 140, electrical path 150 may be used. Electrical path 150 starts at solder ball 149a, travels through the substrate 102 to the bump/pillar 132a, into the interposer 130, and up to the bump/pillar 142a. The electrical path 150 needs to route all the way around the die 110. In this legacy implementation, there is a minimum distance 152, corresponding to a keep out zone, between the closest bump/pillar 132a and the die 110.

Package 101, which may be similar to package 100, shows a perspective view that includes solder balls 149, substrate 102, die 110, interposer 130, processor 140, and I/O die 146. Note that the die 110 may be a significant part of the interposer 130 connection to the substrate 102 depending upon the size and number of dies, and as a result will impact the signal and power integrity of the entire package 101.

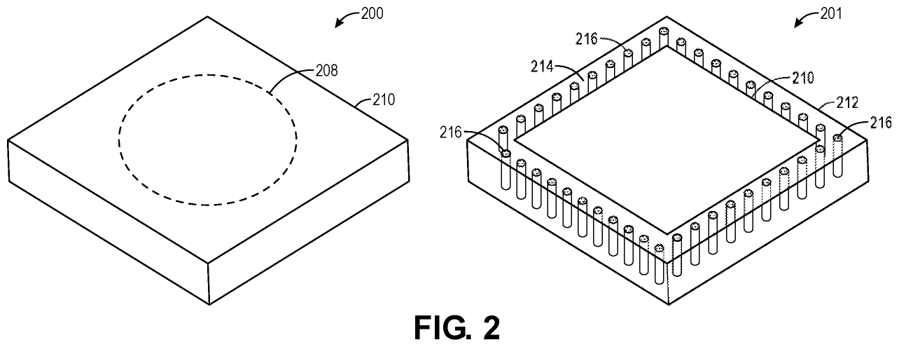

FIG. 2 illustrates perspective views of a die with an active circuitry area and a die with an extended area around the active circuitry area through which vias may be formed, in accordance with various embodiments. Diagram 200 shows a die 210, which may be similar to die 110 of FIG. 1 with an active circuitry area 208, which may be referred to as an active die area, within the die 210. Diagram 201 shows die 212, which includes the die 210 along with an extended area 214 around the die 210. Die 212 may have a first surface on a top of the die 212 and may have a second surface on a bottom of the die 212. In embodiments, the extended area 214 may be created by taking the die 210 and forming the extended area 214 around it. In embodiments, the extended area 214 may be on 1, 2, 3, or all 4 edges of the die 210. In embodiments, all or parts of the active circuitry area 208 or the die 210 may be referred to a being within a first volume of the die 212, and all or parts of the extended area 214 may be referred to as being within a second volume of the die 212.

In embodiments, one or more vias 216 may be formed that extends from a top side of the die 212 through to a bottom side of the die 212. In embodiments, the one or more vias 216 may be referred to as pass-throughs, or pass-through vias. In embodiments, the vias may be a traditional via, or may be elongated to form a plane, or may be a block of material having an arbitrary shape. In embodiments, a conductive material, for example copper, may fill the one or more vias 216 to provide electrical conductivity between both sides of the die 212. In embodiments, a dimension of each of the one or more vias 216 may vary depending upon, for example, whether it is to carry a signal or power.

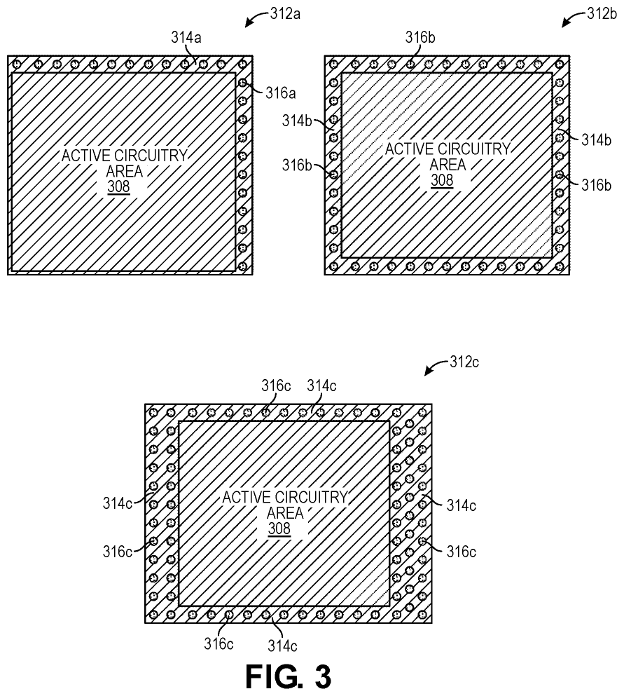

FIG. 3 illustrates top-down views of various configurations of a die with an active circuitry area and an extended area through which vias are formed, in accordance with various embodiments. Die 312a shows an active circuitry area 308 that is partially surrounded by an extended area 314a, which may be similar to active circuitry area 208 and extended area 214 of FIG. 2. A plurality of vias 316a, which may be similar to vias 216 of FIG. 2, may be formed within the extended area 314a on two edges of the active circuitry area 308.

Die 312b shows an active circuitry area 308 that is surrounded by an extended area 314b in that includes vias 316b. As shown, the vias 316b may completely surround the active circuitry area 308 on all four edges. Die 312c shows an active circuitry area 308 that is surrounded by an extended area 314c on all four edges. In embodiments, the vias 316a, 316b, 316c may be placed, respectively in the extended areas 314a, 314b, 314c in varying patterns, not just in a line as shown. This may be referred to as a multi-patterns. In embodiments, the size and geometry of the vias 316a, 316b, 316c may also vary. In embodiments, each of the vias 316a, 316b, 316c are electrically isolated from the active circuitry area 308.

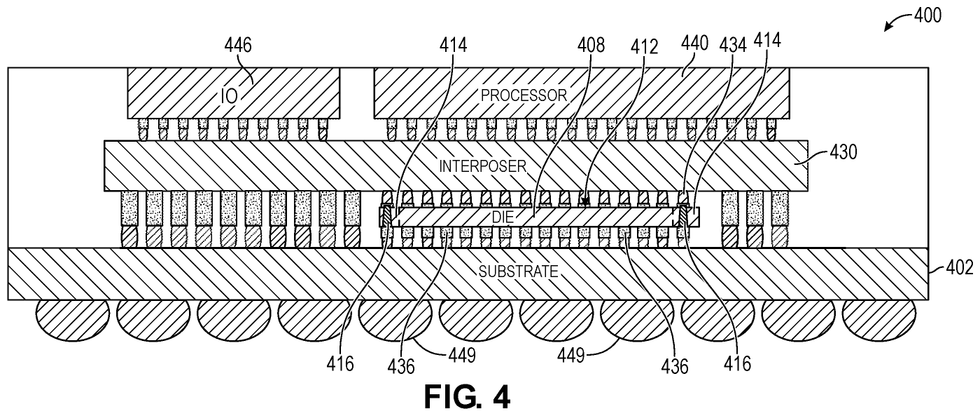

FIG. 4 illustrates a cross-section side view of a structure and example electrical routing of a package that includes a die with active circuitry area and an extended area through which vias are formed, in accordance with various embodiments. Package 400, which may be similar to package 100 of FIG. 1, includes solder balls 449, substrate 402, interposer 430, processor 440, and I/O die 446, which may be similar to solder balls 149, substrate 102, interposer 130, processor 140, and I/O die 146 of FIG. 1.

Die 412, which may be similar to die 212 of FIG. 2, or die 312b of FIG. 3, may be placed between the interposer 430 and the substrate 402. Die 412 may include an active circuitry area 408, surrounded by one or more extended areas 414, with one or more vias 416 in the one or more extended areas 414. In embodiments, the vias 416 passed from a top of the die 412 to a bottom of the die 412. Note that the vias 416 are electrically isolated from any circuitry that may be within the active circuitry area 408.

In embodiments, the vias 416 may be electrically coupled with the substrate 402 through bumps/pillars 436 and may be coupled with the bumps/pillars 434, which may be similar to the bumps/pillars 134 of FIG. 1. Thus, in embodiments, the vias 416 may route signals between the interposer 430 and the substrate 402, or may route power from the substrate 402 to the interposer 430. In embodiments, the signals and/or power may be subsequently routed to the processor 440 or to the I/O die 446, which may be similar to processor 140 and I/O die 146 of FIG. 1.

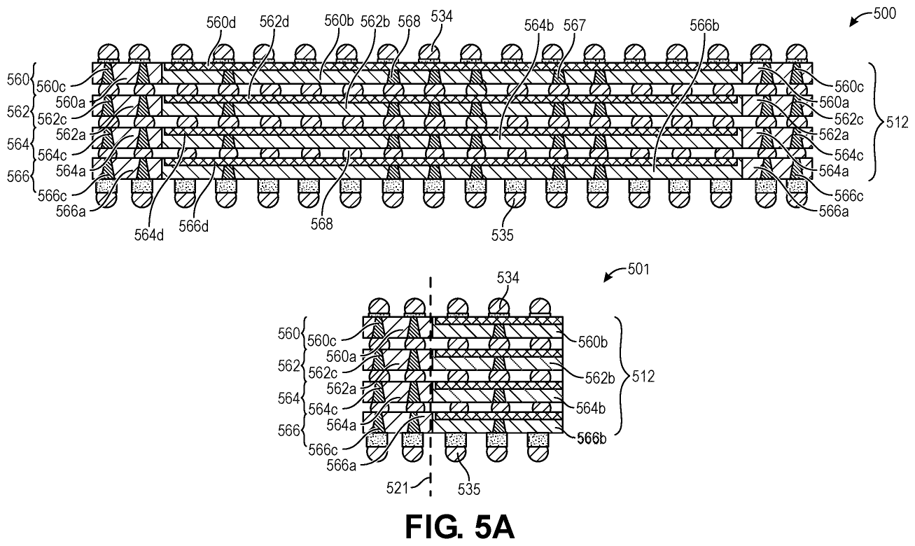

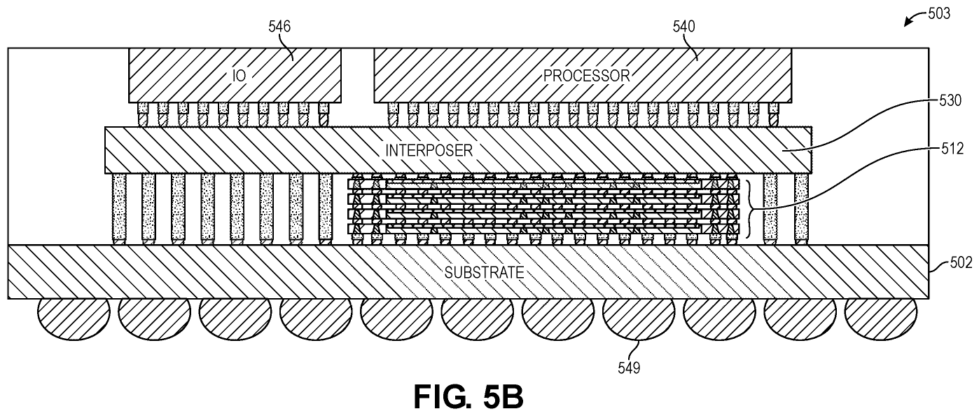

FIGS. 5A-5B illustrate cross-section side views of package that includes multiple stacked dies each with an active circuitry area and an extended area through which vias are formed, in accordance with various embodiments. FIG. 5A includes structure 500 that shows a die stack 512 that includes a plurality of dies 560, 562, 564, 566, each of which may be similar to die 412 of FIG. 4. In embodiments, the plurality of dies 560, 562, 564, 566 may be stacked on each other and electrically coupled with each other using solder balls 568.

In embodiments, each of the plurality of dies 560, 562, 564, 566 include an extended area 560a, 562a, 564a, 566a, which may be similar to extended area 214 of FIG. 2, and an active circuitry area 560b, 562b, 564b, 566b, which may be similar to die 210 of FIG. 2. In embodiments, there may be a transistor layer 560d, 562d, 564d, 566d associated with each of the plurality of dies 560, 562, 564, 566. In embodiments, vias 560c, 562c, 564c, 566c may extend, respectively, through the extended areas 560a, 562a, 564a, 566a and electrically couple with each other. In embodiments, there may be plurality of bumps/pillars 534, which may be similar to bumps/pillars 134 of FIG. 1 at the top of the die stack 512. In embodiments, there may also be a plurality of bumps/pillars 535 at a bottom of the die stack 512. Note that the vias 567 which may provide Z-direction electrical routing between the dies 560, 562, 564, 566, may be used for connecting/routing signals, for example HBM signals, within the die stack 512.

Diagram 501 shows an explosion of structure 500, with a line 521 showing that the vias 560c, 562c, 564c, 566c are electrically isolated from the active circuitry area 560b, 562b, 564b, 566b, and have no functional connection with each other.

FIG. 5B shows package 503 which illustrates a cross-section side view that includes the structure 500 on the substrate 502 and below the interposer 530. In embodiments, the structure 500 may be electrically coupled with the substrate 502 and the interposer 530, and/or with solder balls 549. In embodiments, the I/O die 546 and the processor 540 may be on the interposer 530. In embodiments, the die stack 512 may be an HBM. In embodiments, the I/O die 546, processor 540, interposer 530, substrate 502, and solder balls 549 may be similar to I/O die 446, processor 440, interposer 430, substrate 402, and solder balls 449 of FIG. 4.

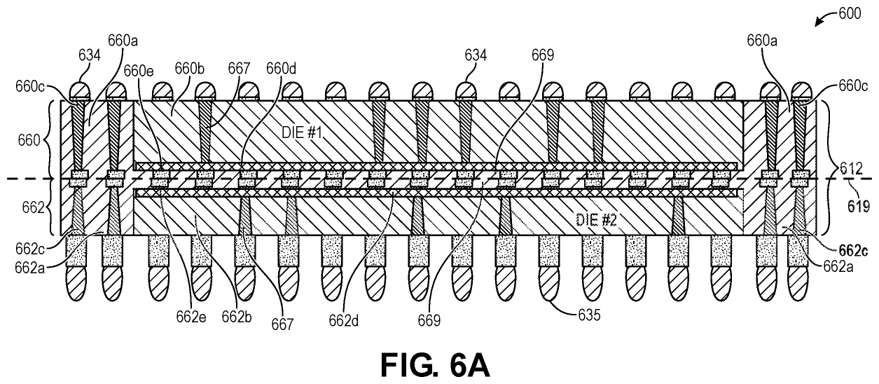

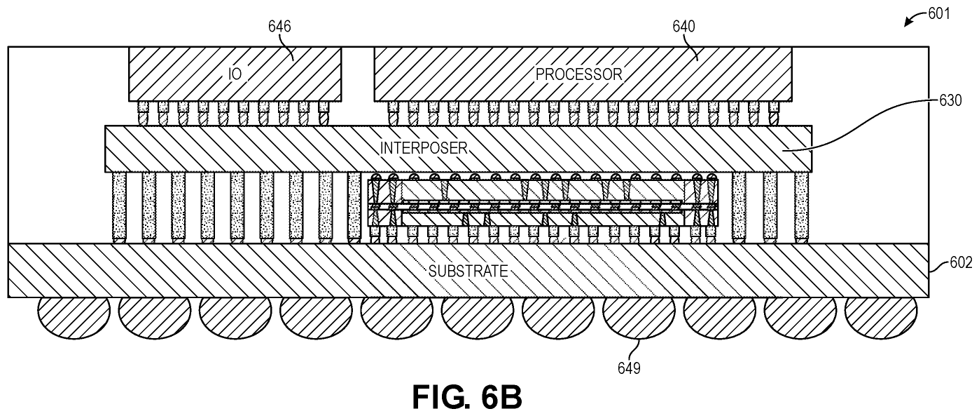

FIGS. 6A-6B illustrate cross-section side views of package that includes two dies that are direct bonded with each other, with each die having an active circuitry area and an extended area through which vias are formed, in accordance with various embodiments. FIG. 6A includes structure 600 that shows a die stack 612, which may be similar to die stack 512 FIG. 5A that includes a first die 660 and the second die 662. In embodiments, the first die 660 and the second die 662 may be connected by direct bonding or hybrid bonding copper to copper along line 619.

In embodiments, the first die 660 may be formed with an active circuitry area 660b with an extended area 660a added to the active circuitry area 660b. The first die 660 may include a transistor layer 660d with copper pads 660e and may be electrically coupled with the transistor layer 660d. In embodiments, vias 667 may electrically couple the transistor layer 660d with one or more bumps/pillars 634 at an opposite side. Within the extended area 660a, vias 660c may be formed and physically and/are electrically coupled with copper pads 660e and with bumps/pillars 634.

In embodiments, the second die 662 may be formed with an active circuitry area 662b with an extended area 662a added to the active circuitry area 662b. The second die 662 may include a transistor layer 662d with copper pads 662e and may be electrically coupled with the transistor layer 662d. In embodiments, vias 667 may electrically couple the transistor layer 662d with one or more bumps/pillars 635 at an opposite side. Within the extended area 662a, vias 662c may be formed and physically and/or electrically coupled with copper pads 662e and with bumps/pillars 635.

In embodiments, during formation of the die stack 612, the copper pads 660e, 662e, may be placed together and then direct bonded to each other. Any dielectric material 669 that may surround the copper pads 660e, 662e may also be bonded, in a hybrid bonding process.

FIG. 6B shows package 601 illustrates a cross-section side view that includes the structure 600 on the substrate 602 and below the interposer 630. In embodiments, the structure 600 may be electrically coupled with the substrate 602 and the interposer 630, and/or with solder balls 649. In embodiments, the I/O die 646 and the processor 640 may be on the interposer 630. In embodiments, the I/O die 646, processor 640, interposer 630, substrate 602, and solder balls 649 may be similar to I/O die 546, processor 540, interposer 530, substrate 502, and solder balls 549 of FIG. 5A.

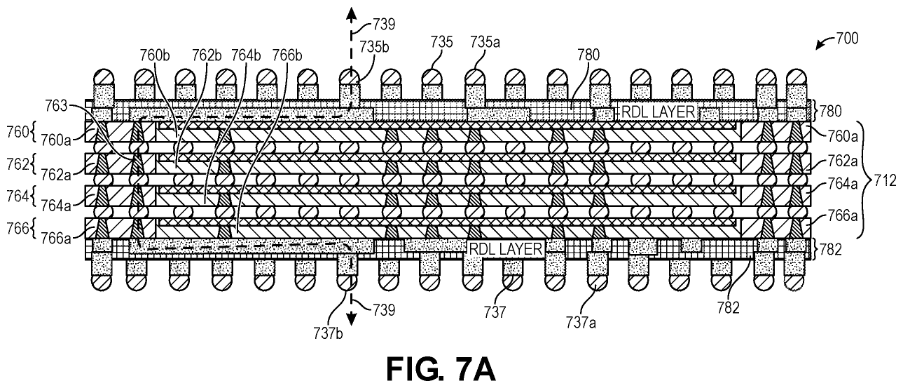

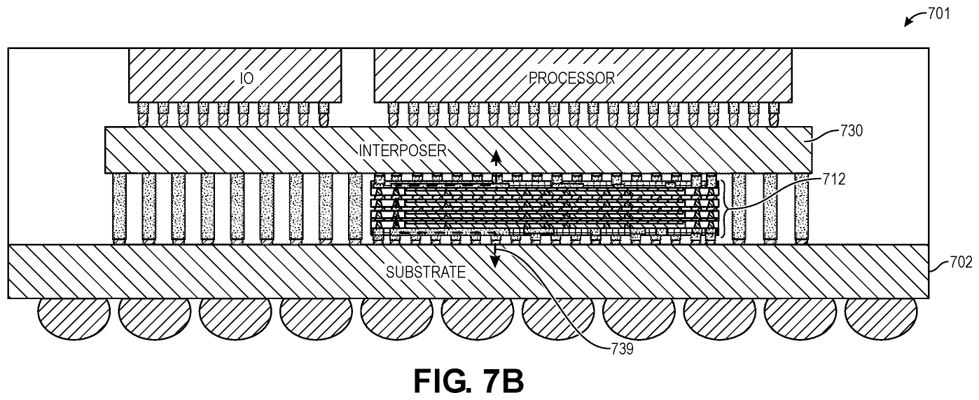

FIGS. 7A-7B illustrate cross-section side views of the package that includes multiple stacked dies each with an active circuitry area and an extended area through which vias are formed, with the top and bottom of the stacked dies including a redistribution layer (RDL) to route power or signals from the vias, in accordance with various embodiments. FIG. 7A includes structure 700 that shows a die stack 712, which may be similar to die stack 512 of FIG. 5A. In embodiments, a top RDL layer 780 may be placed on a top of the die stack 712, and/or a bottom RDL layer 782 may be placed on a bottom of the die stack 712. In embodiments, the RDL layer 780 may have multiple connectors (not shown) that electrically couple with either side, for example the top side or bottom side, of the RDL layer 780.

The die stack 712 may include individual dies 760, 762, 764, 766 that are stacked on each other. Each of the individual dies includes an active circuitry area 760b, 762b, 764b, 766b and an extended area 760a, 762a, 764a, 766a that may include a plurality of vias 763 that are electrically isolated from the active circuitry area 760b, 762b, 764b, 766b. In embodiments, there may be a plurality of bumps/pillars 735 on the top RDL layer 780. In embodiments, some of the plurality of bumps/pillars 735a may be electrically coupled with the active circuitry 760b, 762b, 764b, 766b, and another of the plurality of bumps/pillars 735b may be electrically coupled with the vias 763 within the extended areas 760a, 762a, 762a, 766a. In embodiments, the plurality of bumps/pillars 735a are electrically isolated from the plurality of bumps/pillars 735b.

In embodiments, there may be a plurality of bumps/pillars 737 on the bottom RDL layer 782. In embodiments, some of the plurality of bumps/pillars 737a may be electrically coupled with the active circuitry 760b, 762b, 764b, 766b, and another of the plurality of bumps/pillars 737b may be electrically coupled with the vias 763 within the extended areas 760a, 762a, 762a, 766a. In embodiments, the plurality of bumps/pillars 737a are electrically isolated from the plurality of bumps/pillars 737b.

Electrical path 739 shows an example electrical pathway for power or signal that is provided at bumps/pillars 737b, routes along the bottom RDL 782, through vias 763 in the extended areas 760a, 762a, 762a, 766a, along the top RDL 780, and to bumps/pillars 735b. In embodiments, this electrical path 739 will be functionally isolated from any of the active circuitry within the die stack 712. FIG. 7B package 701 shows the structure 700 of FIG. 7A that is placed on substrate 702 and below the interposer 730.

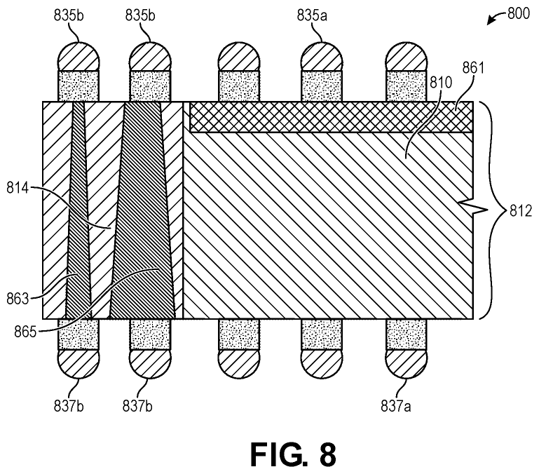

FIG. 8 illustrates a cross-section side view of a die with an active circuitry area and extended area through which vias are formed, where the extended area includes a power via and a signal via, in accordance with various embodiments. Structure 800 includes die 812, which may be similar to die 212 of FIG. 2. In embodiments, the die 812 may include an active circuitry area 810 and an extended area 814, which may be similar to die 210 and extended area 214 of FIG. 2. The active circuitry area 810 may include a transistor layer 861.

In embodiments, bumps/pillars 835a, 837a may be electrically coupled with active circuitry and/or the transistor layer 861 within the active circuitry area 810. In embodiments, bumps/pillars 835b, 837b may be electrically coupled with each other through vias 863, 865. As shown, the vias 863, 865 may have different sizes. For example, the smaller via 863 may be used to route signals around the active circuitry area 810, while the larger via 865 may be used to route power around the active circuitry area 810.

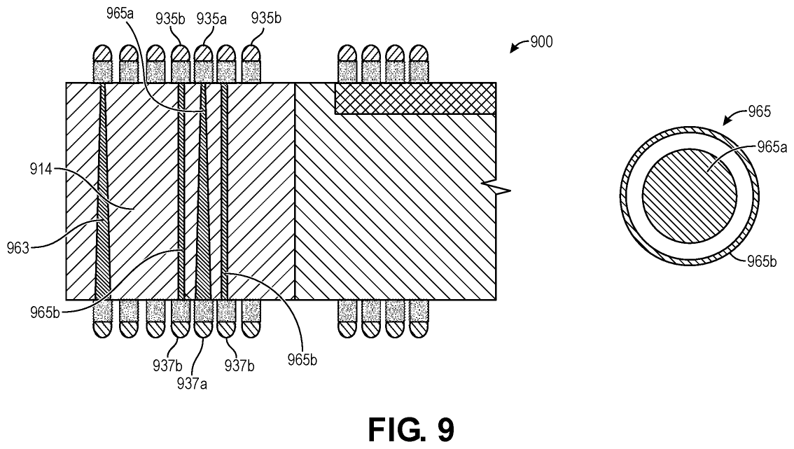

FIG. 9 illustrates a cross-section side view of a die with an active circuitry area and extended area through which vias are formed, where the extended area includes a via that is shielded, in accordance with various embodiments. Structure 900, which may be similar structure 800 of FIG. 8, shows a smaller via 963, which may be similar to smaller via 863 of FIG. 8. However, via 965 may be referred to as a shielded via, with a conductive center 965a that is surrounded by an outer shielding 965b. Both smaller via 963 and via 965 extend through the extended area 914, which may be similar to extended area 214 of FIG. 2.

In embodiments, the conductive center 965a may be electrically coupled with a bump/pillar 935a at a top of the extended area 914, and electrically coupled with a bump/pillar 937a at a bottom of the extended area 914. In embodiments, the outer shielding 965b may be electrically coupled with one or more bumps/pillars 935b at a top of the extended area 914. In embodiments, the outer shielding 965b may be electrically coupled with one or more bumps/pillars 937b at the bottom of the extended area 914. In embodiments, a signal, such as a high-speed signal, may be routed through the conductive center 965a, and the outer shielding 965b may be coupled with a ground.

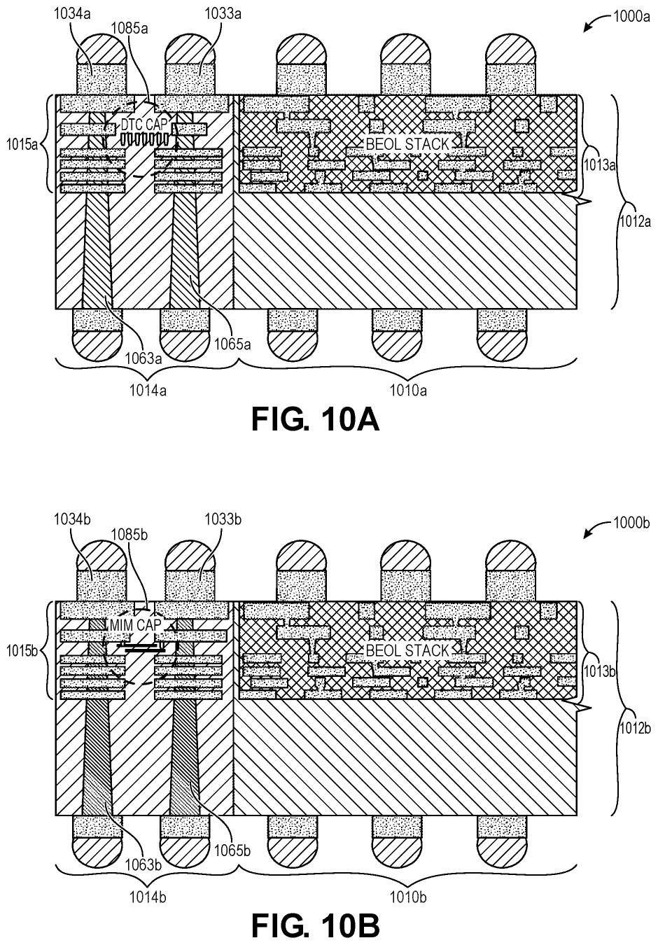

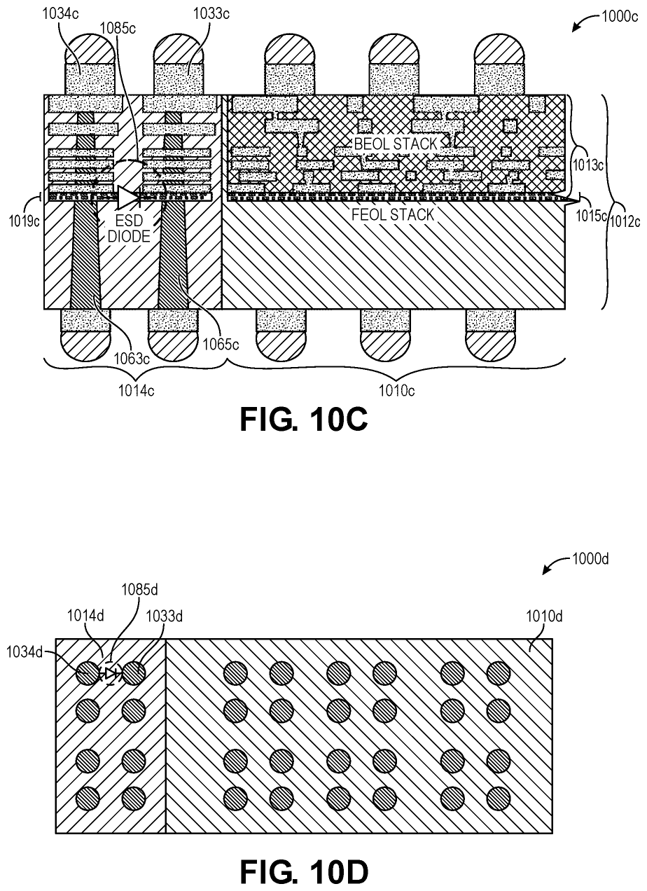

FIGS. 10A-10D illustrate cross-section side views and a top-down view of a die with an active circuitry area and extended area through which vias are formed, where the extended area includes vias that are coupled with each other that form a capacitor or that form a diode, in accordance with various embodiments. FIG. 10A illustrates structure 1000a, which may be similar to structure 700 of FIG. 7A. Structure 1000a may include a die 1012a that includes an extended area 1014a and an active circuitry area 1010a. The die 1012a may include a back end of line (BEOL) stack 1013a.

In embodiments, a BEOL stack 1015a may be formed within the extended area 1014a. In particular, the BEOL stack 1015a may form a deep trench capacitor (DTC) 1085a between a first bump/pillar 1033a and a second bump/pillar 1034a, which may be coupled, respectively, to vias 1063a, 1065a. In embodiments, the DTC 1085a may be formed during BEOL stack manufacturing of a wafer (not shown) in some layers.

In embodiments, when the DTC 1085a is formed between the bumps/pillars 1033a, 1034a, as a result it may have a short distance to upper dies, for example I/O die 446 or processor die 440 of FIG. 4. In embodiments, because the DTC 1085a may be close to a side of an interposer, such as interposer 430 of FIG. 4, the effect of the DTC 1085a may be much higher than if the DTC 1085a were connected as land-side capacitors through the substrate to the processor or I/O dies. An advantage of having the DTC 1085a outside of the active area 1010a, is the fact that the DTC 1085a may otherwise block BEOL routing possibilities. For example the DTC 1085a were placed within the BEOL stack 1013a this would block reuse of a same macro or die design for the die such as die 210 of FIG. 2.

FIG. 10B illustrates structure 1000b, which may be similar to structure 700 of FIG. 7A. Structure 1000b may include a die 1012b that includes an extended area 1014b and an active circuitry area 1010b. The die 1012b may include a back end of line (BEOL) stack 1013b.

In embodiments, a BEOL stack 1015b may be formed within the extended area 1014b. In particular, the BEOL stack 1015b may form a metal insulator metal capacitor (MIM) 1085b, which may be similar to DTC 1085a of FIG. 10A, between a first bump/pillar 1033b and a second bump/pillar 1034b, which may be coupled, respectively, to vias 1063b, 1065b. In embodiments, the MIM 1085b may be formed during a BEOL stack manufacturing of a wafer (not shown) in some layers.

In embodiments, when the MIM 1085b is formed between the bumps/pillars 1033b, 1034b, as a result it may have a short distance to upper dies, for example I/O die 446 or processor die 440 of FIG. 4, without influencing them. An advantage of having the MIM 1085b outside of the active area 1010b, is the fact that the MIM 1085b may otherwise block BEOL routing possibilities.

In embodiments, the DTC 1085a of FIG. 10A or the MIM 1085b of FIG. 10B may be manufactured in different ways, depending upon the functional node process capability of the active areas 1010a, 1010b, for example whether it is a memory. In some embodiments, the DTC 1085a of FIG. 10A or the MIM 1085b of FIG. 10B may be manufactured between several other layers, or in a bulk substrate (not shown) below the transistor level, for example a front end of line (FEOL) level.

FIG. 10C illustrates structure 1000c, which may be similar to structure 700 of FIG. 7A. Structure 1000c may include a die 1012c that includes an extended area 1014c and an active circuitry area 1010c. The die 1012c may include a BEOL stack 1013c and a front end of line (FEOL) stack 1015c.

In embodiments, a FEOL stack 1019c may be formed between the bumps/pillars 1033c, 1034c, which may be coupled, respectively, to vias 1063c, 1065c within the extended area 1014c. In embodiments, an electrostatic discharge (ESD) diode 1085c may be formed within the FEOL stack 1019c. In embodiments, this may be done if, for manufacturer or functional safety reasons, ESD protection is required for the bumps/pillars 1033c, 1034c. In embodiments, integrating the ESD diode 1085c within the FEOL stack 1019c may be done, without additional cost, as the wafer manufacturing process already includes the transistor manufacturing process within an FEOL stack 1019c.

FIG. 10D shows a top-down view of a structure 1000d, which may be similar to structure 1000c of FIG. 10C. In embodiments, structure 1000d may be a die with an active circuitry area 1010d adjacent to an extended area 1014d, which may be similar to active die area 1010c and extended area 1014c of FIG. 10C. In embodiments, bumps/pillars 1033d, 1034d may have an ESD diode 1085d between them, where the ESD diode 1085d may be similar to ESD diode 1085c of FIG. 10C, and may be coupled between vias 1063c, 1065c of FIG. 10C. Note that the configuration of the top features of structure 1000d may be varied, for example based upon the various structures shown and described above with respect to FIG. 3. In one nonlimiting example, an ESD diode 1085d may be coupled with only one via, such as via 1063c of FIG. 10C.

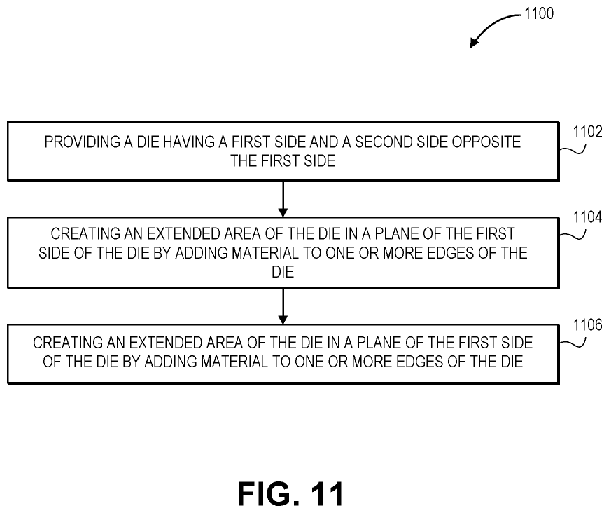

FIG. 11 illustrates an example of a process for creating vias through a die that are electrically isolated from active circuitry in a die, in accordance with various embodiments. Process 1100 may be performed using the system, apparatus, processes, and/or techniques described herein, and in particular with respect to FIGS. 1-10D.

At block 1102, the process may include providing a die having a first side and a second side opposite the first side. In embodiments, the die may be similar to die 110 of FIG. 1, die 210 of FIG. 2 that includes active circuitry area 208, active circuitry area 308 of FIG. 3, or active circuitry area 408 of FIG. 4.

At block 1104, the process may further include creating an extended area of the die in a plane of the first side of the die by adding material to one or more edges of the die. In embodiments, the extended area of the die may be similar to extended area 214 of FIG. 2, extended areas 314a, 314b, 314c of FIG. 3, or extended area 414 of FIG. 4.

At block 1106, the process may further include forming one or more vias in the extended area of the die, wherein the one or more vias extend from a first side of the extended area of the die to the second side of the extended area of the die opposite the first side of the extended area of the die. In embodiments, the vias may be similar to vias 216 of FIG. 2, vias 316a, 316b, 316c of FIG. 3, or vias 416 of FIG. 4.

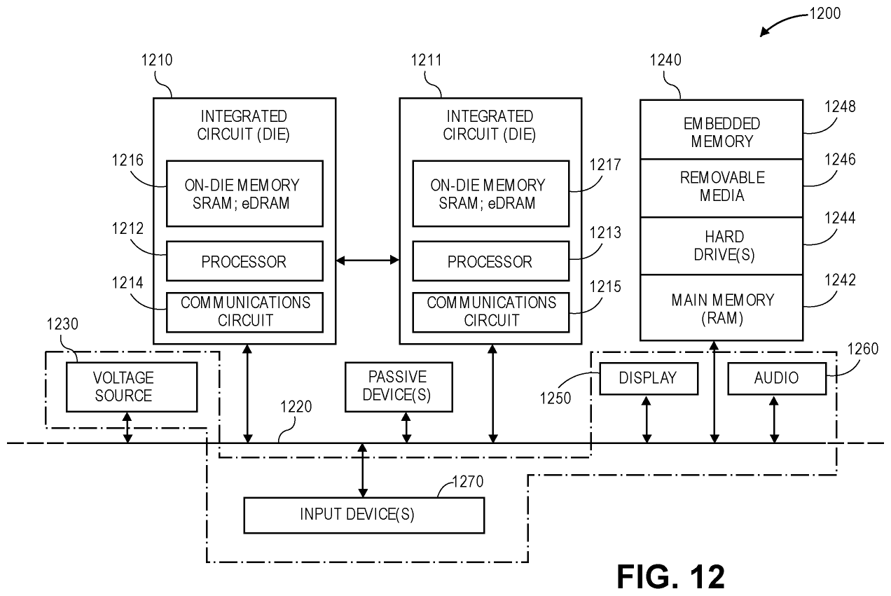

FIG. 12 is a schematic of a computer system 1200, in accordance with embodiments. The computer system 1200 (also referred to as the electronic system 1200) as depicted can embody vias through a die that are electrically isolated from active circuitry in the die, according to any of the several disclosed embodiments and their equivalents as set forth in this disclosure. The computer system 1200 may be a mobile device such as a netbook computer. The computer system 1200 may be a mobile device such as a wireless smart phone. The computer system 1200 may be a desktop computer. The computer system 1200 may be a hand-held reader. The computer system 1200 may be a server system. The computer system 1200 may be a supercomputer or high-performance computing system.

In an embodiment, the electronic system 1200 is a computer system that includes a system bus 1220 to electrically couple the various components of the electronic system 1200. The system bus 1220 is a single bus or any combination of busses according to various embodiments. The electronic system 1200 includes a voltage source 1230 that provides power to the integrated circuit 1210. In some embodiments, the voltage source 1230 supplies current to the integrated circuit 1210 through the system bus 1220.

The integrated circuit 1210 is electrically coupled to the system bus 1220 and includes any circuit, or combination of circuits according to an embodiment. In an embodiment, the integrated circuit 1210 includes a processor 1212 that can be of any type. As used herein, the processor 1212 may mean any type of circuit such as, but not limited to, a microprocessor, a microcontroller, a graphics processor, a digital signal processor, or another processor. In an embodiment, the processor 1212 includes, or is coupled with, vias through a die that are electrically isolated from active circuitry in the die, as disclosed herein. In an embodiment, SRAM embodiments are found in memory caches of the processor. Other types of circuits that can be included in the integrated circuit 1210 are a custom circuit or an application-specific integrated circuit (ASIC), such as a communications circuit 1214 for use in wireless devices such as cellular telephones, smart phones, pagers, portable computers, two-way radios, and similar electronic systems, or a communications circuit for servers. In an embodiment, the integrated circuit 1210 includes on-die memory 1216 such as static random-access memory (SRAM). In an embodiment, the integrated circuit 1210 includes embedded on-die memory 1216 such as embedded dynamic random-access memory (eDRAM).

In an embodiment, the integrated circuit 1210 is complemented with a subsequent integrated circuit 1211. Useful embodiments include a dual processor 1213 and a dual communications circuit 1215 and dual on-die memory 1217 such as SRAM. In an embodiment, the dual integrated circuit 1210 includes embedded on-die memory 1217 such as eDRAM.

In an embodiment, the electronic system 1200 also includes an external memory 1240 that in turn may include one or more memory elements suitable to the particular application, such as a main memory 1242 in the form of RAM, one or more hard drives 1244, and/or one or more drives that handle removable media 1246, such as diskettes, compact disks (CDs), digital variable disks (DVDs), flash memory drives, and other removable media known in the art. The external memory 1240 may also be embedded memory 1248 such as the first die in a die stack, according to an embodiment.

In an embodiment, the electronic system 1200 also includes a display device 1250, an audio output 1260. In an embodiment, the electronic system 1200 includes an input device such as a controller 1270 that may be a keyboard, mouse, trackball, game controller, microphone, voice-recognition device, or any other input device that inputs information into the electronic system 1200. In an embodiment, an input device 1270 is a camera. In an embodiment, an input device 1270 is a digital sound recorder. In an embodiment, an input device 1270 is a camera and a digital sound recorder.

As shown herein, the integrated circuit 1210 can be implemented in a number of different embodiments, including a package substrate having vias through a die that are electrically isolated from active circuitry in the die, according to any of the several disclosed embodiments and their equivalents, an electronic system, a computer system, one or more methods of fabricating an integrated circuit, and one or more methods of fabricating an electronic assembly that includes a package substrate having vias through a die that are electrically isolated from active circuitry in the die, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having vias through a die that are electrically isolated from active circuitry in the die embodiments and their equivalents. A foundation substrate may be included, as represented by the dashed line of FIG. 12. Passive devices may also be included, as is also depicted in FIG. 12.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims.

Rather, the scope is to be determined entirely by the following claims, which are to be construed in accordance with established doctrines of claim interpretation.

### Examples

The following paragraphs describe examples of various embodiments.
Example 1 is an apparatus comprising: a die having a first side and a second side opposite the first side; active circuitry within the die; and one or more vias that extend from the first side of the die to the second side of the die, wherein the one or more vias are electrically isolated from the active circuitry.
Example 2 includes the apparatus of example 1, wherein the one or more vias include an electrically conductive material.
Example 3 includes the apparatus of examples 1 or 2, wherein the active circuitry is within a first volume of the die, wherein the first volume of the die extends from the first side of the die to the second side of the die; and wherein the one or more vias are within a second volume of the die, wherein the second volume of the die extends from an edge of the die to an edge of the first volume of the die.
Example 4 includes the apparatus of example 3, wherein the edge of the die is a first edge of the die; and further comprising wherein the second volume of the die extends to a second edge of the die.
Example 5 includes the apparatus of examples 1, 2, 3, or 4, further comprising one or more electrical contacts on the first side of the die, wherein the one or more electrical contacts electrically couple with the active circuitry within the die.
Example 6 includes the apparatus of examples 1, 2, 3, 4, or 5, wherein the one or more vias include a plurality of vias; and wherein a first one of the plurality of vias and a second one of the plurality of vias are electrically coupled with a selected one or more of: a capacitor or a diode.
Example 7 includes the apparatus of example 6, wherein the capacitor is a selected one or more of: a deep trench capacitor (DTC) or a metal insulator metal (MIM) capacitor.
Example 8 includes the apparatus of examples 1, 2, 3, 4, 5, 6, or 7, wherein the die is a first die; and further comprising: a second die having a first side and a second side opposite the first side, wherein the second die has one or more vias that extend from the first side of the second die to the second side of the second die, wherein the second die is on the first die, and wherein each one of the one or more vias of the first die is electrically coupled with a corresponding one of the one or more vias of the second die.
Example 9 includes the apparatus of examples 1, 2, 3, 4, 5, 6, 7, or 8, further comprising a redistribution layer (RDL) that has a first side and a second side opposite the first side, wherein the second side of the RDL is physically and electrically coupled with the first side of the die, and wherein the RDL electrically couples one of the one or more vias to a connector on the first side of the RDL.
Example 10 includes the apparatus of example 9, wherein the connector on the first side of the RDL is above the active circuitry.
Example 11 includes the apparatus of examples 9 or 10, wherein the RDL is a first RDL, and further comprising a second RDL that has a first side and a second side opposite the first side, wherein the first side of the RDL is coupled with the second side of the die, and wherein the RDL electrically couples the one of the one or more vias to a connector on the second side of the RDL.
Example 12 is a package comprising: a substrate; a die on the substrate, wherein the die has a first side and a second side opposite the first side, wherein the die includes active circuitry and one or more vias that extend from the first side of the die to the second side of the die, wherein the active circuitry is within a first volume of the die, wherein the first volume of the die extends from the first side of the die to the second side of the die, wherein the one or more vias are within a second volume of the die, wherein the second volume of the die extends from an edge of the die to an edge of the first volume of the die, and wherein the one or more vias of the die are electrically coupled with the substrate at the second side of the die; and an interposer on the die, wherein the one or more vias of the die are electrically coupled with the interposer at the first side of the die.
Example 13 includes the package of example 12, wherein the active circuitry is electrically coupled with the interposer at the first side of the die.
Example 14 includes the package of examples 12 or 13, further comprising a die on the interposer, wherein the die is electrically coupled with the substrate through the one or more vias within the die.
Example 15 includes the package of examples 12, 13, or 14, wherein the die is a first die; and further comprising: a second die having a first side and a second side opposite the first side, wherein the second die has one or more vias that extend from the first side of the second die to the second side of the second die, wherein the second die is physically coupled with the first die, and wherein each one of the one or more vias of the first die is electrically coupled with a corresponding one of the one or more vias of the second die.
Example 16 includes the package of examples 12, 13, 14, or 15, further comprising a redistribution layer (RDL) that has a first side and a second side opposite the first side, wherein the second side of the RDL is physically and electrically coupled with the first side of the die, and wherein the RDL electrically couples one of the one or more vias to a connector on the first side of the RDL.
Example 17 includes the package of example 16, wherein the RDL is a first RDL, and further comprising a second RDL that has a first side and a second side opposite the first side, wherein the first side of the RDL is coupled with the second side of the die, and wherein the RDL electrically couples the one of the one or more vias to a connector on the second side of the RDL.
Example 18 includes the package of example 17, wherein the connector on the first side of the first RDL is directly above the active circuitry, and wherein the connector on the second side of the second RDL is directly below the active circuitry.
Example 19 is a method comprising: providing a die having a first side and a second side opposite the first side; creating an extended area of the die in a plane of the first side of the die by adding material to one or more edges of the die; and forming one or more vias in the extended area of the die, wherein the one or more vias extend from a first side of the extended area of the die to the second side of the extended area of the die opposite the first side of the extended area of the die.
Example 20 includes the method of example 19, further comprising placing an electrically conductive material within the one or more vias, and wherein the one or more vias are electrically isolated from active circuitry within the die.

What is claimed is:

1. An apparatus comprising:
a die having a first side and a second side opposite the first side;
active circuitry within the die; and
one or more vias that extend from the first side of the die to the second side of the die, wherein the one or more vias are electrically isolated from the active circuitry.

2. The apparatus of claim 1, wherein the one or more vias include an electrically conductive material.

3. The apparatus of claim 1, wherein the active circuitry is within a first volume of the die, wherein the first volume of the die extends from the first side of the die to the second side of the die; and
wherein the one or more vias are within a second volume of the die, wherein the second volume of the die extends from an edge of the die to an edge of the first volume of the die.

4. The apparatus of claim 3, wherein the edge of the die is a first edge of the die; and further comprising wherein the second volume of the die extends to a second edge of the die.

5. The apparatus of claim 1, further comprising one or more electrical contacts on the first side of the die, wherein the one or more electrical contacts electrically couple with the active circuitry within the die.

6. The apparatus of claim 1, wherein the one or more vias include a plurality of vias; and wherein a first one of the plurality of vias and a second one of the plurality of vias are electrically coupled with a selected one or more of: a capacitor or a diode.

7. The apparatus of claim 6, wherein the capacitor is a selected one or more of: a deep trench capacitor (DTC) or a metal insulator metal (MIM) capacitor.

8. The apparatus of claim 1, wherein the die is a first die; and further comprising:
a second die having a first side and a second side opposite the first side, wherein the second die has one or more vias that extend from the first side of the second die to the second side of the second die, wherein the second die is on the first die, and wherein each one of the one or more vias of the first die is electrically coupled with a corresponding one of the one or more vias of the second die.

9. The apparatus of claim 1, further comprising a redistribution layer (RDL) that has a first side and a second side opposite the first side, wherein the second side of the RDL is physically and electrically coupled with the first side of the die, and wherein the RDL electrically couples one of the one or more vias to a connector on the first side of the RDL.

10. The apparatus of claim 9, wherein the connector on the first side of the RDL is above the active circuitry.

11. The apparatus of claim 9, wherein the RDL is a first RDL, and further comprising a second RDL that has a first side and a second side opposite the first side, wherein the first side of the RDL is coupled with the second side of the die, and wherein the RDL electrically couples the one of the one or more vias to a connector on the second side of the RDL.

12. A package comprising:
a substrate;
a die on the substrate,
wherein the die has a first side and a second side opposite the first side,
wherein the die includes active circuitry and one or more vias that extend from the first side of the die to the second side of the die,
wherein the active circuitry is within a first volume of the die,
wherein the first volume of the die extends from the first side of the die to the second side of the die,
wherein the one or more vias are within a second volume of the die,
wherein the second volume of the die extends from an edge of the die to an edge of the first volume of the die, and
wherein the one or more vias of the die are electrically coupled with the substrate at the second side of the die; and
an interposer on the die, wherein the one or more vias of the die are electrically coupled with the interposer at the first side of the die.

13. The package of claim 12, wherein the active circuitry is electrically coupled with the interposer at the first side of the die.

14. The package of claim 12, further comprising a die on the interposer, wherein the die is electrically coupled with the substrate through the one or more vias within the die.

15. The package of claim 12, wherein the die is a first die; and further comprising:
a second die having a first side and a second side opposite the first side, wherein the second die has one or more vias that extend from the first side of the second die to the second side of the second die, wherein the second die is physically coupled with the first die, and wherein each one of the one or more vias of the first die is electrically coupled with a corresponding one of the one or more vias of the second die.

16. The package of claim 12, further comprising a redistribution layer (RDL) that has a first side and a second side opposite the first side, wherein the second side of the RDL is physically and electrically coupled with the first side of the die, and wherein the RDL electrically couples one of the one or more vias to a connector on the first side of the RDL.

17. The package of claim 16, wherein the RDL is a first RDL, and further comprising a second RDL that has a first side and a second side opposite the first side, wherein the first side of the RDL is coupled with the second side of the die, and wherein the RDL electrically couples the one of the one or more vias to a connector on the second side of the RDL.

18. The package of claim 17, wherein the connector on the first side of the first RDL is directly above the active circuitry, and wherein the connector on the second side of the second RDL is directly below the active circuitry.

19. A method comprising:
providing a die having a first side and a second side opposite the first side;
creating an extended area of the die in a plane of the first side of the die by adding material to one or more edges of the die; and
forming one or more vias in the extended area of the die, wherein the one or more vias extend from a first side of the extended area of the die to the second side of the extended area of the die opposite the first side of the extended area of the die.

20. The method of claim 19, further comprising placing an electrically conductive material within the one or more vias, and wherein the one or more vias are electrically isolated from active circuitry within the die.
